(19) United States
(12) Patent Application Publication
(10) Pub. No.: US 2014/0202334 A1
(43) Pub. Date: Jul. 24, 2014

(54) FILTER SYSTEM AND METHOD FOR LEAK IDENTIFICATION

(71) Applicant: BHA Altair, LLC, Franklin, TN (US)

(72) Inventors: Alston Ilford Scipio, Mableton, GA (US); Sanji Ekanayake, Mableton, GA (US); Luis Alberto Soto Romero, Queretaro (MX)

(73) Assignee: BHA Altair, LLC, Franklin, TN (US)

(21) Appl. No.: 13/748,115

(22) Filed: Jan. 23, 2013

(51) Int. Cl. B03C 3/34; H05K 3/00

(52) U.S. Cl. CPC B03C 3/34; H05K 3/00
USPC 96/26; 29/593; 96/80

(57) ABSTRACT

A filter system and method utilizing a plurality of filters each with an electrically conductive material portion for conducting an electric current while the filter maintains a tight seal and for not conducting the electric current when the filter does not maintain the tight seal.

### BACKGROUND OF THE INVENTION

The subject matter disclosed herein relates to a system for detecting the loss of sealing integrity in an air filtration system, in particular, in a filter house having numerous filter elements.

Air filtration systems for large gas turbines employ filter houses having numerous filter elements positioned on tube sheets. The filters are held securely in place by various mechanical means under sufficient pressure to provide an air tight seal such that there are no gaps through which dirty air can bypass the filter elements. Mounting devices and methods for securing the filter elements tend to vary with filter house design, location, filter type, and manufacturer. Widely used retaining instruments include clamps, and locking nut and bolt arrangements. Such mechanical devices are subject to vibrations caused by motors and air flow which loosens mechanically secured devices eventually resulting in loss of air tight seals between the filter elements and the tube sheets. Improper sealing of the filters provides an avenue, e.g., a gap, for dirty air to bypass the filter. Improper sealing can also be caused by improper initial installation, poor quality of installation materials, and distortion in the filter element sealing surface, all of which may not be discovered by visual inspection. The bypass of filter elements by dirty, particulate laden air can accelerate loading of another filter in a downstream location and can accelerate wear and erosion of mechanical components in, for example, a gas turbine compressor.

Current filter house designs can comprise hundreds of filter elements. Auxiliary systems monitor relative humidity, ambient temperature, and other parameters that are critical to, for example, gas turbine performance. A common premise is that all the air entering the compressor is pure air that has passed through the air filtration system. Opacity detectors, e.g., photodetectors, are often used to monitor incoming air to infer that there is a leak in the filter grid of such systems via detected changes in opacity caused by airborne contaminants such as dust or other particles. However, such detection systems do not pinpoint where a sealing flaw is located.

The discussion above is merely provided for general background information and is not intended to be used as an aid in determining the scope of the claimed subject matter.

### BRIEF DESCRIPTION OF THE INVENTION

A filter system and method utilizing a plurality of filters each with an electrically conductive material portion for conducting an electric current while the filter maintains a tight seal and for not conducting the electric current when the filter does not maintain the tight seal. Advantages that may be realized in the practice of some disclosed embodiments of the filter leak detection system includes increased mechanical performance of systems that rely on a properly filtered air supply, automatic identification of the location of a leak, decreased mechanical erosion, fewer shutdowns due to component failures, and reduction in maintenance costs.

One embodiment comprises a filter system having a tube sheet with a plurality of filter elements disposed on it. The filter elements each have an electrically conductive material portion in electrical contact with a voltage source when the filter elements maintain a tight seal on the tube sheet. The electrically conductive material portions are not in electrical contact with the voltage source if the filter elements do not maintain the tight seal.

Another embodiment comprises a filter house having at a voltage source and a plurality of mounting locations for receiving filter elements that have electrically conductive material portions. The mounting locations each have an electrical contact for connecting the electrically conductive material portion of the filter elements to the voltage source.

Another embodiment comprises disposing an electrically conductive circuit on a tube sheet for contacting electrically conductive filter elements installed on the tube sheet, and installing the filter elements on the tube sheet. Electrical characteristics of the filter elements are monitored after the installation.

This brief description of the invention is intended only to provide a brief overview of subject matter disclosed herein according to one or more illustrative embodiments, and does not serve as a guide to interpreting the claims or to define or limit the scope of the invention, which is defined only by the appended claims. This brief description is provided to introduce an illustrative selection of concepts in a simplified form that are further described below in the detailed description. This brief description is not intended to identify key features or essential features of the claimed subject matter, nor is it intended to be used as an aid in determining the scope of the claimed subject matter. The claimed subject matter is not limited to implementations that solve any or all disadvantages noted in the background.

### BRIEF DESCRIPTION OF THE DRAWINGS

So that the manner in which the features of the invention can be understood, a detailed description of the invention may be had by reference to certain embodiments, some of which are illustrated in the accompanying drawings. It is to be noted, however, that the drawings illustrate only certain embodiments of this invention and are therefore not to be considered limiting of its scope, for the scope of the invention encompasses other equally effective embodiments. The drawings are not necessarily to scale, emphasis generally being placed upon illustrating the features of certain embodiments of the invention. In the drawings, like numerals are used to indicate like parts throughout the various views. Thus, for further understanding of the invention, reference can be made to the following detailed description, read in connection with the drawings in which:

FIG. 1 is a representation of a portion of an exemplary filter house;

FIG. 2 is a representation of an exemplary filter system in the filter house of FIG. 1;

FIG. 3 is another representation of an exemplary filter system in the filter house of FIG. 1;

FIG. 4 is a flow chart of a process for establishing an exemplary filter system; and

FIG. 5 is a flow chart of a process for monitoring the exemplary filter system of FIG. 3.

### DETAILED DESCRIPTION OF THE INVENTION

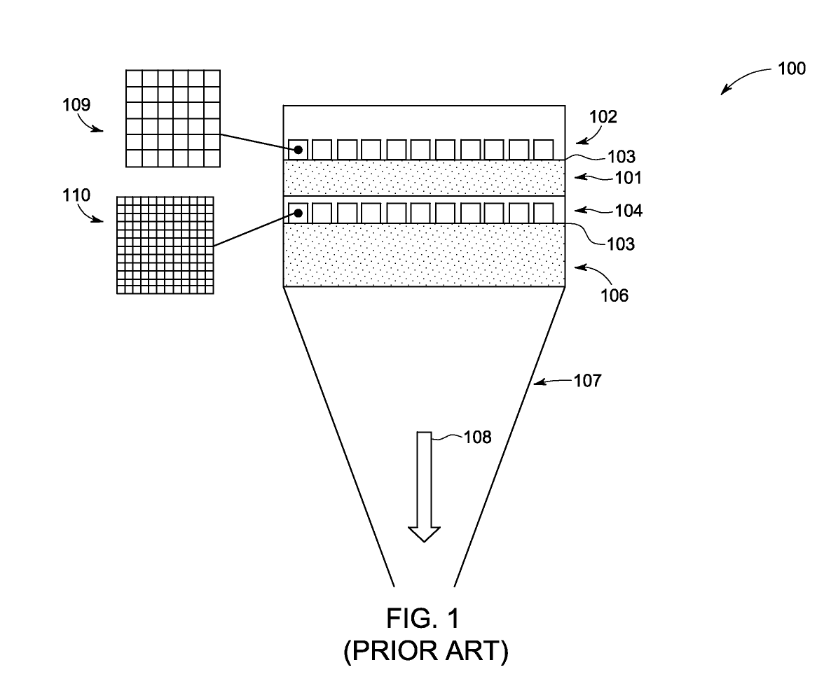

FIG. 1 illustrates an embodiment of a portion of filter house 100 wherein a first matrix of filter elements 102 is disposed on a tube sheet 103 to provide a first stage of air filtration. This first stage of air filtration may comprise a coarse filtration to remove larger particles from air passing through an air duct, such as conduit 107, toward, for example, gas turbine compressors. The filter media 109 in the first stage filter elements 102 may be configured to admit finer particles while trapping coarser particles. Air that is filtered by the first stage filtration enters a first filter zone 101 wherein the air may be measured for various properties such as opacity, humidity and temperature. A second matrix of filter elements 104 is disposed on a tube sheet 103 to further filter air from the first filter zone 101. This second stage of air filtration may comprise finer filter media 110 to remove smaller particles from the air that will pass into second filter zone 106 wherein the filtered air may again be measured for various properties, as described above. In the side view if FIG. 1 one row each of filter elements 102, 104 are visible, however, multiple rows of filter elements 102 and 104 form the first matrix and the second matrix of filter elements on the tube sheets 103, as described herein. Filtered air exits the second filter zone 106 and continues through conduit 107 in the direction indicated by the arrow 108. The air is typically drawn through the filter house 100 by compressor suction at sufficient pressure to force incoming air through the two stages of filter elements. The matrix of filter elements 102, 104 are positioned on tube sheets 103 with sufficient pressure, such as provided by mechanical retainers, so as to divert air through the filter elements 102, 104 and to prevent gaps from forming between filter elements 102, 104 and the tube sheets 103 whereby dirty air might bypass the filter elements 102, 104 and continue traveling through the conduit 107.

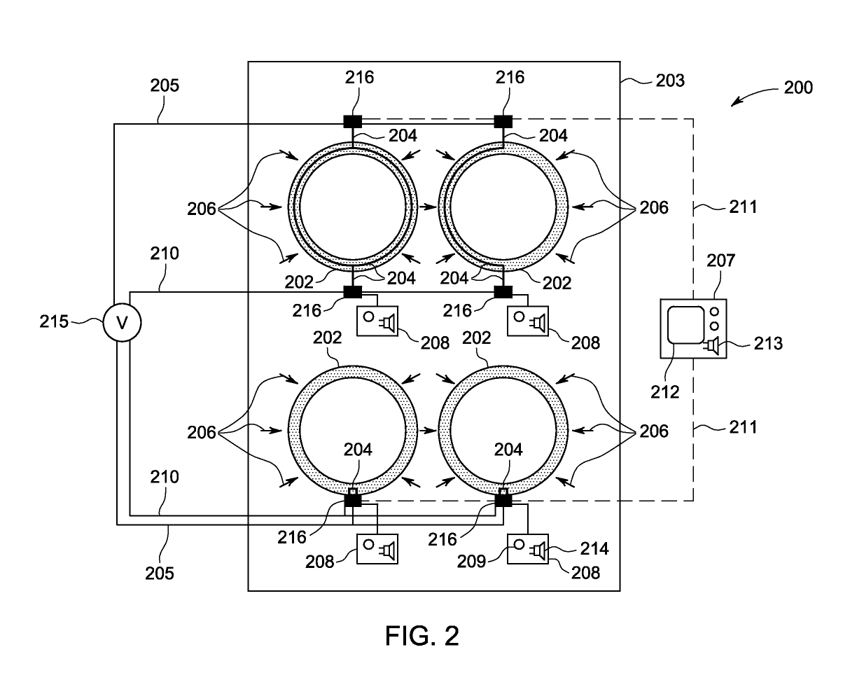

FIG. 2 illustrates an embodiment of a filter system 200, which may be located in a filter house such as illustrated in FIG. 1. The filter system 200 comprises a plurality of filter elements 202, such as air filters, each disposed in a conduit 107, which carries a gas, such as air, through the filter elements 202 in a direction indicated by the arrows 206. The tube sheet 203 includes voltage lines 205, 210 connected to the voltage source 215. The filter elements 202 each have a filter medium 109 or 110 for filtering air passing therethrough and an electrically conductive material portion 204 for connecting to the voltage lines 205, 210 when the filter elements 202 are in a properly installed position on the tube sheet 203. The filter elements 202 are each properly installed in the conduit 107 at a mounting location 216 on the tube sheet 203 when the electrically conductive material portion 204 of the filter element 202 closes the electric circuit formed by voltage source 215 and voltage lines 205, 210.

The mounting locations 216 are each defined by an electrical contact, or electrical terminal, wherein the electrically conductive portions 204 of filter elements 202 may electrically contact the voltage lines 205, 210. The mounting locations 216, and the positioning of the electrically conductive material portion 204 on each filter element 202, are selected such that when the circuit is closed by the filter element 202, as just described, the filter element 202 is properly installed and provides an air tight seal against the tube sheet 203 of the conduit 107. Therefore, any air traveling through conduit 107 has passed through the filter media 109 or 110 of properly installed filter elements 202 and cannot bypass the filter elements 202. The mounting locations 216, the electrically conductive material portions 204, or the voltage lines 205, 210, or a combination thereof, may comprise resistive elements to control an amount of current flowing therethrough. As described below, the resistive elements may be selectively sized in order to provide more precision in identifying failing filter elements 202.

The filter elements 202 are disposed on the tube sheet 103 in the conduit 107 for filtering particles from the air traveling through the conduit 107. The air is typically drawn through the filter house by the compressor suction. As viewed in FIG. 2, the filter elements 202 in the upper portion of FIG. 2 each comprise an electrically conductive material portion 204 that extends between two mounting locations 216. Thus, there are two mounting locations 216 for each of these filter elements 202 which require their electrically conductive material portions 204 to contact the voltage lines 205, 210 at two corresponding electrical contact points. In the lower portion of FIG. 2, the filter elements 202 each comprise an electrically conductive material portion 204 that contacts one mounting location having spaced electrical contact points for closing the electrically conductive circuit with voltage lines 205, 210. In one embodiment, the electrically conductive material portions 204 of each pair of the filter elements 202, as seen in FIG. 2, are connected in parallel between voltage lines 205, 200. The electrically conductive material portions 204 on the filter elements 202 may be variously formed and positioned, as shown in the embodiments of FIG. 2, from any conductive material in any form, such as a conductive coating, printed circuit, adhesive, wire, rod, tape, resistor, or other form, that is capable of reliably closing the electric circuit formed by voltage lines 205, 210 and voltage source 215.

As described above, such a closed electric circuit occurs when a filter element 202 is tightly sealed against tube sheet 203 such as may be accomplished by a mechanical retainer exerting a sufficient pressure upon the filter element 202. Such a closed electric circuit will draw a small amount of electric current, and an open or closed electric circuit can be easily detected by electrical devices connected thereto. As described above, a resistive element may be introduced into the closed electric circuit, such as in the electrically conductive material portions 204, in the voltage lines 205, 210, or in the mounting locations 216. Such resistive elements may include known resistances. An improperly installed, or dislodged, filter element 202 will alter electrical characteristics of its corresponding electric circuit which may be automatically detected by a monitoring detector 208 or control station 207, as described below. These changed characteristics can be automatically, electrically detected without requiring manual or visual inspection of the installation of filter element 202. Such changed characteristics include a different amount of current flowing through the voltage lines for a particular conduit and a different resistance presented by the electric circuit formed in a particular conduit.

In one embodiment, detectors 208 are electrically connected to each of the closed circuits formed by voltage source 215, voltage lines 205, 210, and the electrically conductive material portion 204 of filter elements 202 that are properly secured at mounting locations 216 on the tube sheet 203, through which a small current flows. If the circuit opens, such as by filter 202 becoming disengaged from its properly mounted position, the small current ceases flowing and this changed electrical characteristic is sensed by detector 208. The detector 208 may include a visual indicator 209, such as an LED, which can be configured to either illuminate or to turn off when the abnormal condition is sensed, depending on its standard default state. The detector 208 may include an audible indicator 214 which also can be configured for activation to indicate that the changed electrical characteristic is sensed. A plurality of detectors 208 can each be connected to the closed circuit formed at, or in proximity to, each filter 202 mounting location 216, thereby providing a visual and/or audible notification when an air tight seal fails, with the added advantage of pointing out, by proximity to, the failing seal.

In one embodiment, a control station 207 may be connected, via electrical lines 211, as shown in FIG. 2, to all of the closed circuits formed by the filter elements 202 installed at mounting locations 216. The control station 207 may include a display screen 212 and/or a speaker 213 for providing a visual and/or an audible notification upon detecting an open circuit caused by a failing seal. The control station 207 may include a microprocessor, or controller, with memory for storing programs executed by the microprocessor, as described herein, or for storing other information that is accessible by the microprocessor to perform monitoring tasks as described herein. The control station 207 may be located proximate to the filter system 200 or may be connected remotely by electrical lines 211. The control station 207 may display information on display screen 212 identifying the filter element 202 whose seal is failing. The control station 207 may be embodied in a programmed computer, such as a personal computer, a tablet computer, a handheld processing system, a microcontroller, or some other programmed processing unit. The control station 207 may include a wireless communication capability for transmitting radio signal information to another remote processing unit for conveying status information about the filter system 200 or information about a detected failing seal.

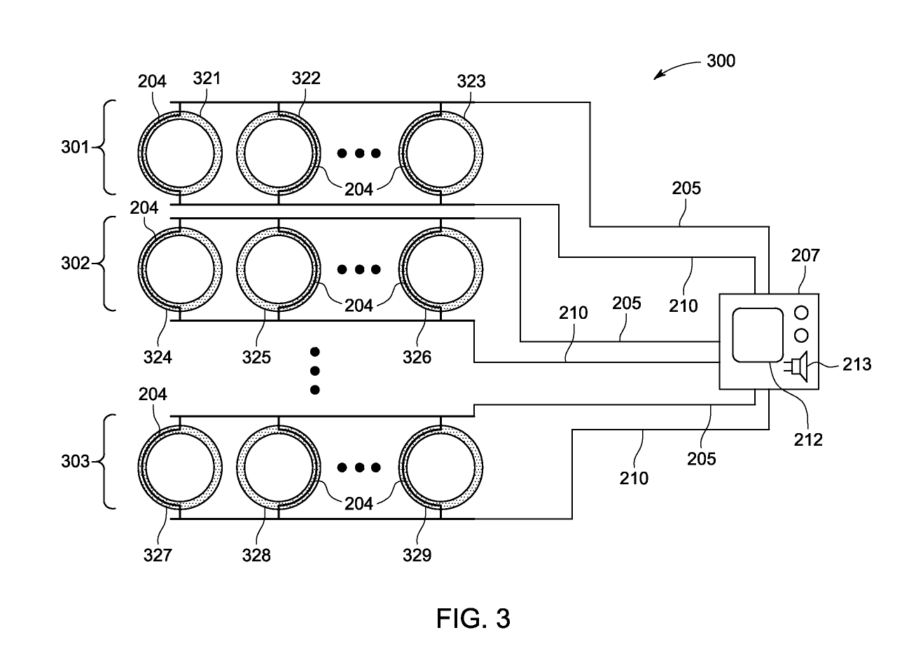

With reference to FIG. 3, there is illustrated an embodiment of a filter system 300, similar to the embodiments of filter system 200 described and shown in FIG. 2 except that several components are not depicted for purposes of clarity and ease of illustration. The embodiments illustrated in FIG. 3 should be understood to be capable of implementing every feature of the filter system 200 as described in relation to FIG. 2 above. As shown, filter system 300 may comprise any number of conduits 301-303 with any number of filter elements 321-329 installed therein. As illustrated, filter elements 321-323 are installed in corresponding conduit 301; filter elements 324-326 are installed in corresponding conduit 302; and filter elements 327-329 are installed in corresponding conduit 303. The filter elements 321-329 comprise electrically conductive material portions 204 that are connected in parallel within each conduit 301-303 to voltage lines 205, 210, so long as the filter elements 321-329 remain properly installed to provide air tight seals in the conduits 301-303. Although not shown in FIG. 3, filter system 300 may include detectors such as the detectors 208 of FIG. 2 that are operable in the same fashion as explained above with reference to FIG. 2.

In one embodiment, voltage lines 205, 210 are all connected to the control station 207. In this embodiment the control station 207 includes a voltage source connected to voltage lines 205, 210 for driving a small detectable current through the electrically conductive material portions 204 in filter elements 321-329. The control station 207 further includes one or more digital ammeters or ohmmeters for monitoring the small amount of current flowing between voltage lines 205, 210 corresponding to each of the conduits 301-303 or for measuring a resistance of the electric circuit corresponding to each of the conduits 301-303. If one of the filter elements 321-329 becomes dislodged, the failure is detected by the one or more digital ammeters or ohmmeters in control station 207 because the electrically conductive material portion 204 of the dislodged filter element 321-329 will be disconnected from either or both voltage lines 205, 210 and the total current flowing through, or the total resistance of, the remaining electrically conductive material portions 204 in the corresponding conduit 301-303 changes in an amount that can be detected by control station 207. The expected current magnitude can easily be calculated at the control station processor using the well know electrical property I=V/R. In one embodiment the voltage level of the voltage source 215 is known, as well as the size of resistance elements in each closed circuit formed by installed filter elements 321-329.

The control station 207 may be configured by appropriate programming to store a selectable threshold current and/or resistance level and, in response to detecting that the current or resistance has changed and exceeds the threshold, to identify the corresponding conduit 301-303 where the change has occurred. Thus, in this embodiment, a dislodged filter element 321-329 can be more easily located by identifying the conduit 301-303 where the malfunction has occurred.

The control station 207 may include a display screen 212 and/or a speaker 213 for providing a visual and/or an audible notification upon detecting the malfunctioning filter element 321-329, such as a text message on display screen 212 or a pre-recorded audio replayed over speaker 213. The control station 207 may be located proximate to the filter system 300 or it may be connected remotely by voltage lines 205, 210. The control station 207 may be programmed to automatically display information on display screen 212 or to replay an audio message over speaker 213 identifying the corresponding conduit 301-303 having a filter element 321-329 whose seal has failed. The control station 207 may be embodied in a programmed computer, such as a personal computer, a tablet computer, a handheld processing system, a microcontroller, or some other programmed processing unit. The control station 207 may include a wireless communication capability for transmitting radio signal information to another remote processing unit for conveying information about one of the conduits 301-303 having a dislodged filter element 321-329.

In another embodiment, the resistances of the electrically conductive material portions 204 of filter elements 321-329 may be individually selected to provide known resistances to the voltage supplied by connected voltage lines 205, 210. As a result, the expected current flowing through voltage lines 205, 210 for each conduit 301-303, as well as a total resistance of each conduit 301-303, can be calculated. Furthermore, the expected current magnitudes flowing through, and resistances of, voltage lines 205, 210 for each conduit 301-303 can be calculated for every possible combination of one or more failing filter elements 321-329. By employing a different, known resistance for each of the electrically conductive material portions 204 within each conduit 301-303, and recording the position of the known resistances corresponding to each filter element 321-329 location within the conduits 301-303, the failing filter element can be pinpointed based on the numerical value of the decreased current flow. The failing filter element can also be pinpointed based on the numerical value of the remaining resistance provided by the known resistive elements connected in parallel. Thus, at least two electrical characteristics of each conduit can be used to determine whether a filter element has become dislodged and, if so, its location.

As an illustrative example, if each of the electrically conductive material portions 204 of filter elements 321-323 in conduit 107 comprises a different preselected resistance element, and one of the filter elements 321-323 becomes dislodged, the decreased current level flowing through the remaining filter elements 321-323 can be calculated based on the voltage level of voltage lines 205, 210 and on the known resistances of the remaining parallel connected filter elements 321-323 in the conduit 107. Because each filter element 321-323 will decrease the current level by a different amount if it becomes dislodged, a one-to-one correspondence between the numerical value of the decreased current level and each filter element 321-323 can be determined and stored in a table in a memory accessible by control station 207. Similarly, such a table can be generated and stored which corresponds to the total resistance presented by the remaining filter elements.

The control station 207 may be configured to store a table of expected current magnitudes, or resistance magnitudes, for each conduit 301-303 corresponding to possible combinations of one or more failing filter elements 321-329 together with locations of each of the filter elements 321-329. Thus, the control station 207 may be programmed such that when a changed current or changed resistance is detected in one or more of the conduits 301-303 the conduit can be thereby identified, and the magnitude of the decreased current or resistance, as measured by the one or more digital ammeters and ohmmeters in control station 207, can be looked up in the stored table to identify precisely which one or more filter elements 321-329 have failed and where they are located.

As explained above with respect to FIG. 2, the electrically conductive material portions 204 on the filter elements 321-329 may be variously fabricated from any conductive material in any form, such as a conductive coating, printed circuit, adhesive, wire, rod, tape, resistor, or other form, that is capable of reliably electrically connecting to voltage lines 205, 210. In addition, known resistors can be connected in line with the electrically conductive material portions 204, in the mounting locations 216, or in the voltage lines 205, 210, to provide a known resistance corresponding to each filter element 321-329. Such resistors can be directly attached to the filter elements 321-329 in their electrically conductive material portions 204 during manufacture of the filter elements 321-329, or afterwards.

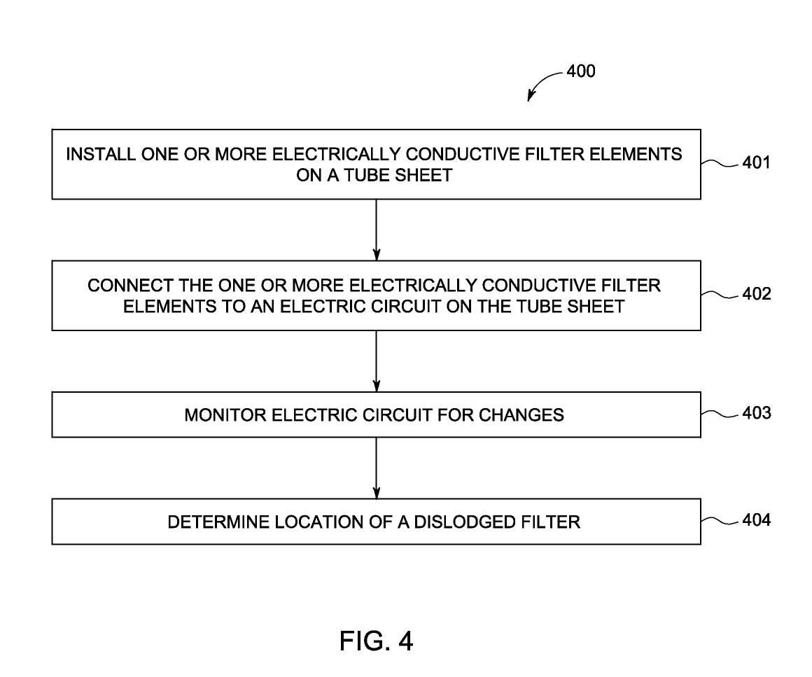

FIG. 4 illustrates a method of implementing one embodiment wherein filter elements 202 are installed at mounting locations 216 on a tube sheet 203 and monitored to ensure that they are properly seated on the tube sheet 203. In a first step, step 401, a filter element 202 having an electrically conductive portion 204 is installed on a tube sheet 203 having voltage lines 205, 210 attached thereto at mounting locations 216. The installation of the filter element 202 continues at step 402 wherein the electrically conductive portions 204 of the filter elements 202 are electrically connected to the voltage lines on the tube sheet 203. This step may require that the filter element 202 be fastened to the tube sheet 203 using mechanical means such as retainers that will exert sufficient pressure so as to establish good electrical contact between the electrically conductive portion 204 on the filter element and the voltage lines 205, 210 on the tube sheet 203. As described above, the voltage lines 205, 210 on the tube sheet 203, as well as the electrically conductive portions 204 on the filter element 202, may be variously fabricated from any conductive material in any form, such as a conductive coating, printed circuit, adhesive, wire, rod, tape, resistor, or other form, that is capable of reliably establishing electrical contact. After the electrical connections are established the corresponding circuits can be automatically monitored using a control station 207 or detector 208 as described above, in step 403. The circuits are monitored for changes in electrical characteristics, such as resistance or current flow, and, when such changes are detected, the location of a filter element 202 is indicated by a detector 208 connected to the filter element 202 circuit or determined by a control station 207 connected to the filter element circuit, in step 404. A magnitude of change in the electrical characteristics of a corresponding circuit is used to determine a location of a failing filter element 202 as described above.

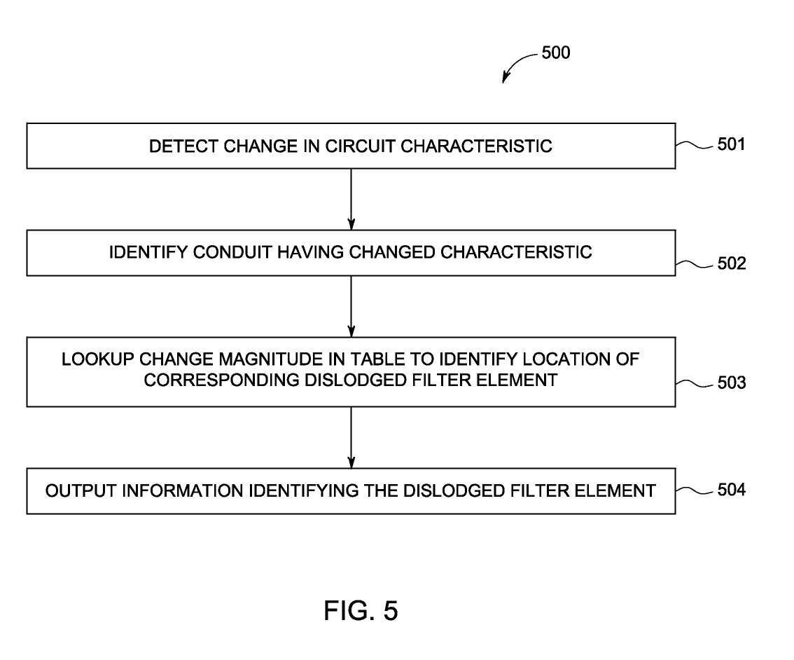

FIG. 5 illustrates, in the form of a flowchart, a method 500 performed by a control station 207 under programmed control to detect malfunctioning filter elements 321-329. The control station 207 is programmed to monitor the current flowing through each conduit 301-303 of the filter system 300, or the resistance of the circuit through each conduit, or a combination thereof, either continuously or periodically using the one or more digital ammeters, or ohmmeters, in the control station 207, and to compare the monitored current level or resistance level with a stored numerical threshold value. At step 501, the control station 207 detects that the current level or resistance level in one or more of the conduits 301-303 has changed. In response, at step 502, the control station identifies the one or more conduits, either 301, 302, or 303, where the electrical characteristic has changed. At step 503, the numerical value of the changed characteristic is looked up in an electronic table to identify a corresponding malfunctioning filter element 321-329. The filter elements 321-329 are stored in the table each in association with the numerical values of various possible changed current and resistance levels for each conduit 301-303 based on all possible combinations of malfunctioning filter elements 321-329. At step 504, the control station 207 outputs information identifying the dislodged filter element 321-329 on its display screen 212, through its speaker 213, wirelessly over a radio channel to another processing unit, or a combination thereof.

In view of the foregoing, embodiments of the invention provide a system and method for automatically detecting a disengaged filter element in a filter house. A technical effect is to increase mechanical performance and lifetimes of systems relying on a properly filtered air supply.

As will be appreciated by one skilled in the art, aspects of the present invention may be embodied as a system, method, or computer program product. Accordingly, aspects of the present invention may take the form of an entirely hardware embodiment, an entirely software embodiment (including firmware, resident software, micro-code, etc.), or an embodiment combining software and hardware aspects that may all generally be referred to herein as a “control station” “circuit,” “circuitry,” and/or “system.” Furthermore, aspects of the present invention may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

Program code and/or executable instructions embodied on a computer readable medium may be transmitted using any appropriate medium, including but not limited to wireless, wireline, optical fiber cable, RF, etc., or any suitable combination of the foregoing.

Computer program code for carrying out operations for aspects of the present invention may be written in any combination of one or more programming languages, including an object oriented programming language such as Java, Smalltalk, C++ or the like and conventional procedural programming languages, such as the “C” programming language or similar programming languages. The program code may execute entirely on the user's computer (device), partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present invention are described herein with reference to flowchart illustrations and/or block diagrams of methods, apparatus (systems) and computer program products according to embodiments of the invention. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

What is claimed is:

1. A filter system comprising:
a tube sheet;
a voltage source; and
a plurality of filter elements disposed on the tube sheet and each comprising an electrically conductive material portion, wherein the electrically conductive material portion is in electrical contact with the voltage source when its filter element maintains a tight seal on the tube sheet, and wherein the electrically conductive material portion is not in electrical contact with the voltage source when its filter element does not maintain the tight seal.

2. The filter system according to claim 1, wherein the plurality of filter elements comprise air filters and the tight seal comprises an air tight seal.

3. The filter system according to claim 2, wherein the electrically conductive material portions in the filter elements are each electrically connected to a separate indicator having two states, a first one of the two states indicating that the filter element is maintaining the air tight seal, and a second one of the two states indicating that the filter element is not maintaining the air tight seal, the indicator providing an audible indication, a visual indication, or a combination thereof.

4. The filter system according to claim 2, wherein the electrically conductive material portions in the filter elements are all electrically connected to a control station, the control station comprising a display screen for providing visual information identifying the filter element that does not maintain the air tight seal.

5. The filter system according to claim 4, wherein the control station comprises a circuit for sending a wireless a notification signal to a remotely located device including information identifying the filter element that does not maintain the air tight seal.

6. The filter system according to claim 1, further comprising a plurality of filter mounting locations connected to the voltage source, each of the filter mounting locations comprising an electric contact for electrically coupling the electrically conductive material portion of a corresponding one of the plurality of filter elements to the voltage source when the corresponding one of the plurality of filter elements maintains the tight seal.

7. The filter system according to claim 1, wherein the electrically conductive material portions of the plurality of filters are connected in parallel to the voltage source, and wherein the system further comprises an ammeter for measuring a total level of current flowing through the electrically conductive material portions of the plurality of filters.

8. The filter system of claim 7, further comprising a table storing information for identifying which one or more of the filter elements is not maintaining the tight seal based on the total level of current flowing through the electrically conductive material portions of the plurality of filters.

9. The filter system according to claim 1, wherein the electrically conductive material portions of the plurality of filters are connected in parallel to the voltage source, and wherein the system further comprises an ohmmeter for measuring a total amount of resistance presented by the electrically conductive material portions of the plurality of filters.

10. A filter house comprising:
at least one voltage source; and
a plurality of mounting locations each for receiving a filter element that includes an electrically conductive material portion, the mounting locations each comprising an electrical contact electrically connected to the at least one voltage source for electrically coupling the electrically conductive material portion of the filter element to the voltage source.

11. The filter house according to claim 10, further comprising at least one indicator each electrically connected to one of the electrical contacts for indicating whether the electrically conductive material portion of the filter element is coupled to the voltage source.

12. The filter house according to claim 10, wherein the mounting locations are disposed on a tube sheet, the tube sheet for channeling a gas through the filter element installed at one of the mounting locations.

13. The filter house according to claim 10, further comprising a control station electrically connected to all of the electrical contacts for indicating whether the electrically conductive material portion of a filter element is connected thereto.

14. The filter house according to claim 13, wherein the control station comprises an ammeter, an ohmmeter, or a combination thereof, for measuring a level of current flowing through the electrical contacts, a resistance level of a circuit comprising the electrical contacts, or a combination thereof.

15. The filter house according to claim 14, wherein the control station further comprises a table storing location information of a dislodged filter element associated with the measured level of the current, the measured resistance level, or a combination thereof.

16. A method comprising the steps of:
disposing an electrically conductive circuit on a tube sheet for making electrical contact to at least one electrically conductive filter element installed on the tube sheet;
installing the at least one electrically conductive filter element on the tube sheet; and
monitoring an electrical characteristic of the electrically conductive circuit after the step of installing.

17. The method of claim 16, further comprising determining whether the at least one filter element is properly installed based on the step of monitoring.

18. The method of claim 17, wherein the step of monitoring comprises determining an amount of electric current flowing through the electrically conductive circuit.

19. The method of claim 17, wherein the step of monitoring comprises determining a resistance of the electrically conductive circuit.

20. The method of claim 16, further comprising:
installing a plurality of the electrically conductive filter elements on the tube sheet;
determining an electrical characteristic of the electrically conductive circuit; and
determining a location of a dislodged filter element based on the electrical characteristic of the electrically conductive circuit.
